(19) United States
(12) Patent Application Publication
(10) Pub. No.: US 2015/0168482 A1
(43) Pub. Date: Jun. 18, 2015

(54) CONFIGURABLE TEST EQUIPMENT

(71) Applicants: Todd M. Flynn, Austin, TX (US); Christopher W. Argento, Dripping Springs, TX (US); Steven A. Faillaci, Austin, TX (US); Thomas H. Lee, Austin, TX (US)

(72) Inventors: Todd M. Flynn, Austin, TX (US); Christopher W. Argento, Dripping Springs, TX (US); Steven A. Faillaci, Austin, TX (US); Thomas H. Lee, Austin, TX (US)

(21) Appl. No.: 14/104,602

(22) Filed: Dec. 12, 2013

(51) Int. Cl. G01R 31/26; G01R 1/067; G01R 1/04; G01R 31/28

(52) U.S. Cl. CPC G01R 31/2601; G01R 31/2834; G01R 1/067; G01R 1/0408; G01R 31/2889

(57) ABSTRACT

An electronic component test device capable of testing electronic components in a plurality of test configurations. The device includes a probe head for providing a plurality of probe contact structures to an electronic component to be tested. The device includes an interconnect board coupled to the probe head. The interconnect board includes a plurality of conductive terminals, each of a first subset of the plurality of conductive terminals is coupled to one of a group of electrical signal lines for coupling to different types of external signals. The interconnect board includes a plurality of conductive lines. Each conductive line is coupled between a corresponding one of a plurality of conductive terminals in a second subset of the plurality of conductive terminals and a terminal for coupling to one of the plurality of probe contact structures. Each conductive terminal of the second subset is couplable by an interconnector of a plurality of interconnectors to a conductive terminal of multiple conductive terminals of the first subset based on a test configuration of the device.

### BACKGROUND OF THE INVENTION

1. Field of the Invention

This invention relates in general to test equipment for electronic components and more specifically to test equipment that is configurable.

2. Description of the Related Art

Test equipment such as Automatic Test Equipment (ATE) is used to test electronic components. The tests are typically performed by the manufacturer prior to shipment to a customer. In one example, semiconductor manufacturers test circuits on a wafer prior to singulation of the wafer. However, tests can be performed after singulation as well.

With some testing, a probe card with probe pins are brought into contact with conductive structures of the electronic components being tested. Electrical signals are then conveyed through the pins and measurements are made to determine whether the component being tested is operating properly.

### BRIEF DESCRIPTION OF THE DRAWINGS

The present invention may be better understood, and its numerous objects, features, and advantages made apparent to those skilled in the art by referencing the accompanying drawings.

FIG. 1 is a block diagram of a test system according to one embodiment of the present invention.

FIG. 2 is a top view of a probe card interconnect board according to one embodiment of the present invention.

FIG. 3 is schematic view of conductive terminals of a probe card interconnect board according to one embodiment of the present invention.

FIG. 4 is a bottom view of a probe head according to one embodiment of the present invention.

FIG. 5 is a bottom view of a probe head according to another embodiment of the present invention.

FIG. 6 is a cutaway side view of a probe card and wafer according to one embodiment of the present invention.

The use of the same reference symbols in different drawings indicates identical items unless otherwise noted. The Figures are not necessarily drawn to scale.

### DETAILED DESCRIPTION

The following sets forth a detailed description of a mode for carrying out the invention. The description is intended to be illustrative of the invention and should not be taken to be limiting.

A probe card is disclosed herein that includes an interconnect board that allows for signals lines to be individually and selectively routed to different probe contact structures (e.g. probe pins) of a probe card. The different signal lines carry different types of electrical signals (e.g. information signals, power, and ground). Conductive terminals located on the interconnect board are coupled to the probe contact structures and are in proximity to conductive terminals connected to the signal lines such the probe conductive structures can be selectively coupled to at least one of the signal lines. In addition, in some embodiments, the probe card includes a probe head with openings for receiving probe contact structures that allow for the probe head contact structures to be selectively added or removed to allow for a different number of external conductive structures (e.g. bumps, pads, solder balls, pillars) and/or a different configuration of the external conductive structures for different electrical components.

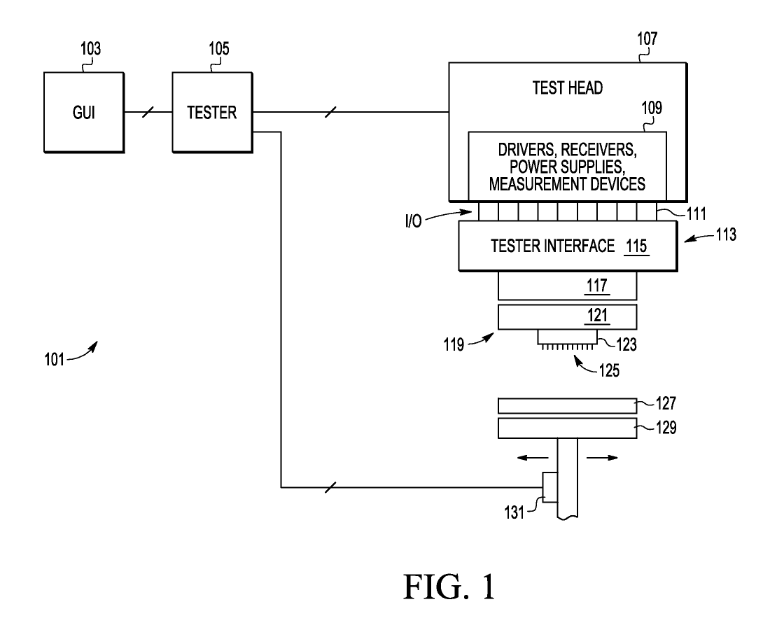

FIG. 1 is a block diagram of a test system 101 for testing an electrical component. In the embodiment shown, system 101 includes a graphical user interface 103, tester 105, test head 107, interface 113, probe card 119, chuck 129, and chuck controller 131. Tester 105 includes a computerized control system for controlling the operations of system 101. GUI 103 includes a screen and user input devices (e.g. keyboard, mouse) for user control and observation of test results. Test head 107 includes test circuitry 109 for generating information signals, power signals, ground signals, and for analyzing information signals received from the tests. Test circuitry 109 may include transducers, drivers, receivers, power supplies (regulators, generators, converters), metrology units, comparators, pattern generators, clocks, timing circuit generators, and measurement devices. Other test heads may include other types of test circuitry in other embodiments.

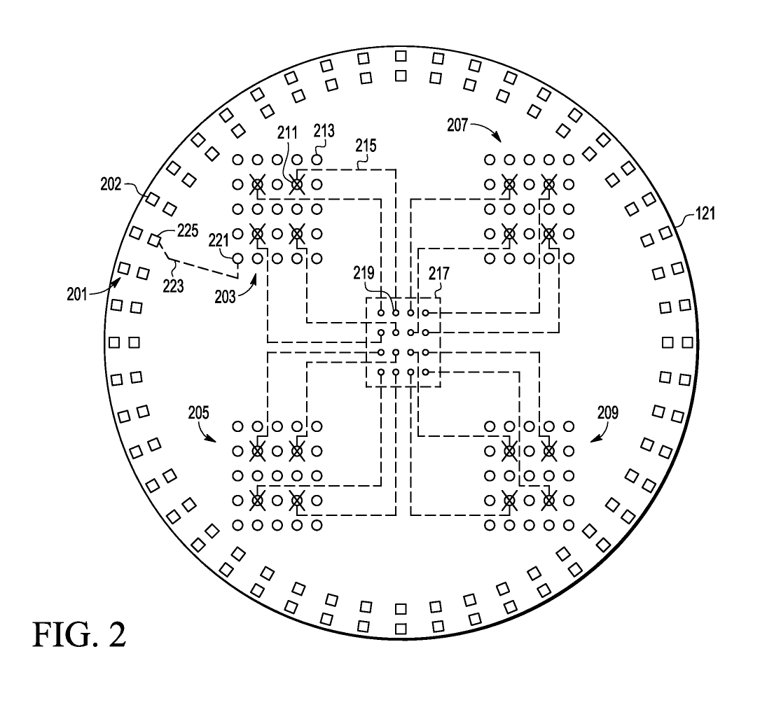

Test head 107 has external electrical conductors 111 (e.g. pins, pads or other types of external conductors) for conveying signals with the probe card 119 via an interface 113. Interface 113 provides a mechanism for conveying signals between test head 107, whose external conductors 111 have one physical layout, and probe card 119, whose external conductors (e.g. pads) have a different physical layout. In the embodiment shown, interface 113 has an interface board 115 (e.g. a circuit board) and a pogo tower 117. The pogo tower 117 includes pogo pins for contacting external conductors of probe card 119 (e.g. pads 201 of FIG. 2). During testing operations, interface 113 is attached to test head 107 and probe card 119 (e.g. with screws or other attachment devices). In other embodiments, interface 113 may have other configurations and/or structures. Still in other embodiments, test system 101 does not include an interface 113 where the probe card 119 is attached to test head 107 during operation.

Probe card 119 includes an interconnect board 121 that has external conductive structure (e.g. pads 201) that contact external conductive structures of pogo tower 117 (e.g. pogo pins). Interconnect board 121 includes conductive structures (e.g. circuit traces) that carry signals to terminals that can be selectively coupled to other terminals of board 121 that are coupled to probe contact structures (e.g. probe pins 125) of probe head 123. The probe pins 125 contact electrically conductive structures (e.g. pads, bumps, posts, solder balls) of the device under test (a die of wafer 127) to convey electrical signals for testing.

In the embodiment shown, wafer 127 is supported by chuck 129. Chuck 129 is positioned by a chuck controller 131 to move the wafer laterally so that a specific part of the wafer 127 can be tested. In some embodiments, the test head 107 (with probe card 119 and interface 113 attached) moves vertically to bring probe head 123 to wafer 127. In other embodiments, chuck 129 is movable in a vertical direction.

System 101 can perform a number of tests on wafer 127 to determine whether devices of wafer 127 were manufactured properly. For example, system 101 can perform scan tests, built in self tests (BISTs), memory tests (RAM, NVM) parametric measurements, analog block tests, and current measurements. Other types of testing operations may be performed in other embodiments. In one embodiment, tester 105 and test head 107 are sold by Teradyne Inc. of North Redding, Mass. under the trade designation of Teradyne J750. However, other testers and test head equipment may be utilized in other embodiments.

In the embodiment shown, the device being tested is a portion (e.g. a die site) of a wafer that will subsequently be singulated into multiple die. In some embodiments, multiple die of a wafer can be tested at one time. In other embodiments, the device under test is a singulated die. Still in other embodiments, the device under test is a packaged integrated circuit or multiple packaged integrated circuits.

FIG. 2 is a top view of interconnect board 121 according to one embodiment. In the view shown, interconnect board 121 is a disc shaped printed circuit board having a diameter of approximately one foot. In other embodiments, the interconnect board may have another shape, another configuration, be made of other materials, and/or be of other sizes. Surrounding the perimeter of board 121 are a number of external connectors (e.g. pads 201) that contact corresponding electrical connectors (e.g. pogo pins) from tower 117. These pads (referred to as “signal pads”) are used to convey signals between test head 107 and conductive structures of board 121.

Board 121 includes four groups of conductive terminals (groups 203, 205, 207, and 209) located in interior regions of board 121 that are utilized to selectively couple test circuitry of test head 107 to probe pins 125. In the embodiment shown, each group has twenty five conductive terminals. Groups of other embodiments may include a different number of terminals (e.g. 150 in some embodiments). Also in other embodiments, a board may have a different number of groups. In one embodiment, the terminals are conductive through-hole pins fixably attached in an orientation perpendicular and extending out from the top surface of board 121. In other embodiments, the terminals are of another conductive terminal type such as surface mount pins, pads, posts, conductive sockets, receivers, switch inputs, circuit inputs, or leads. In some embodiments, some of the terminals of a group may be of one terminal type while other terminals may be of another type.

A first set of terminals of each group (203) are each coupled to a signal pad (e.g. 202) located at the perimeter of board 121. In FIG. 2, these terminals (e.g. terminals 221, 213) are represented by open circles. The terminals of the first set (referred to as “signal side” terminals) are used to convey signals of the test head. In the embodiment of FIG. 2, each of the signal side terminals (e.g. 213) is connected to a signal pad (e.g. 202) located on the perimeter by a circuit trace embedded in board 121. For example, terminal 221 is connected to embedded trace 223, which is connected to pad 225. The other embedded traces of board 121 connected to the signal side terminals and perimeter signal pads are not shown in FIG. 2 in order to reduce its complexity.

A second set of terminals (e.g. 211) of each group of terminals are each coupled to a pad (219) located on the bottom side of board 121. In FIG. 2, these terminals (referred to as “probe side” terminals) are represented by circles with an X. These terminals are coupled to the pads on the bottom of board 121 by traces (e.g. 215) embedded in board 121. For example, terminal 211 is connected to embedded trace 215 which is connected to underside pad 219. The underside pads are located in an area 217 where probe head 123 is attached to the underside of board 121.

In other embodiments, the circuit traces may be located on a surface of board 121. Also in other embodiments, board 121 may have mechanical stiffeners (not shown) attached to the top side to provide structural support to the board. Also in some embodiments, the embedded signal lines (e.g. 215) may be connected to other terminals (such as receptacles or pads) that can be used to couple other circuitry (e.g. resistors, capacitors, inductors, or active circuitry) to the probe pins. Also in other embodiments, other electrical components may be attached to board 121.

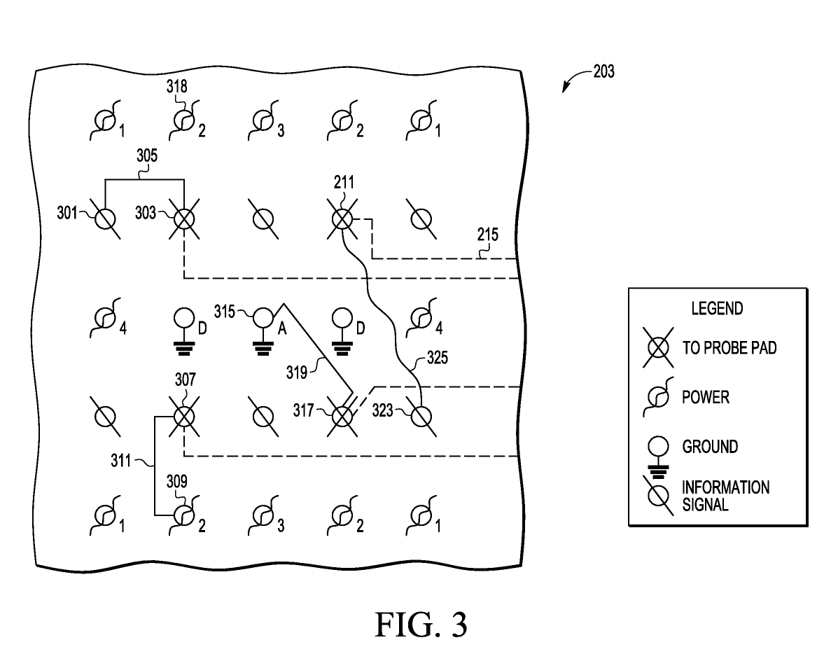

FIG. 3 shows a closer top view of a group 203 of terminals according to one embodiment. The four probe side terminals (211, 303, 307, and 317) are coupled to under side pads (219) that are couplable to probe pins 125. Some of the signal side terminals (e.g. 309) are power pins that convey different voltages (as designated by the different subscript numbers) or voltages for different types of circuitry such as a digital circuitry or an analog circuitry. Other signal side terminals (e.g. 315) are ground terminals. Terminal 315 is an analog ground terminal (as designated by the “A” subscript). Another type of ground terminal is a digital ground terminal (as designated by the “D” subscript).

Another type of signal side terminal shown in FIG. 3 is an information signal terminal for providing information signals between the test head and probe pins. Examples of information signals include metrology signals for taking/reading analog measurements from a device under test, analog drive signals to a device under test, digital signals for reading and writing information to a device under test, clock signals, timing signals, and communication signals. The terminals of the other terminal groups 207, 205, and 209 may be arranged accordingly.

In the embodiment shown, interconnectors are used to selectively couple the power, ground, and information signal side terminals to the probe side terminals to selectively couple the probes (e.g. 125) of the probe head 123 to different signal lines of the test head. For example, jumper 305 couples probe side terminal 303 to information signal terminal 301 to coupled the test channel of terminal 301 to a probe. Diagonal jumper 319 is used to couple ground terminal 315 to probe side terminal 317. Jumper 311 is used to couple probe side pin 307 to voltage terminal 309. The jumpers are manually removable in some embodiments. Wire 325 is used to couple probe terminal 211 to information signal terminal 323.

Other types of interconnects that may be used to couple the terminals includes switches, dip switches, electrical-mechanical relays, solid state relays, multiplexers, resistors, and receptacles. In some embodiments, the interconnects are mounted to the board where the terminals are located. In some embodiment, the interconnects may be electrically settable (such as with relays or multiplexers) such that the couplings between the signal side terminals and the probe side terminals are controlled by processing circuitry.

In order to change the test configuration for testing a different type of electronic component, the jumpers and wires (or other types of interconnects) are rearranged to couple the probe side terminals (e.g. 303) to different signal side terminals according to the desired use of a probes pin during the tests. For example, jumper 305 can be moved so as to couple probe side terminal 303 to voltage terminal 318. Accordingly, in this second test configuration, the probe coupled to probe side terminal 303 would be used to provide a voltage during the test. Each of the other probe side terminals can also be selectively coupled to a signal side terminal according to its desired use during the tests.

Providing the signal side and probe side terminals in close proximity to each other allows for the probe contact structures to be configured to carry different types of signals depending upon the type of components being tested. Thus, any probe may be able to carry any type of voltage, any type of ground, or any type of information signal by interconnecting the probe side terminal to the desired signal side terminal.

Although in the embodiment shown, each interconnect is connected to only one probe side terminal and only one of either a power, ground, or information signal side terminal, in other implementations, multiple probe side pins can be coupled to a power, ground, or information signal terminal. Also, multiple power, ground, and information signal side terminals can be couple to a probe side terminal. For example, two probe side terminals can be grounded by coupling both of them to one ground terminal. Also, two information signal side terminals can be coupled to one probe side terminal.

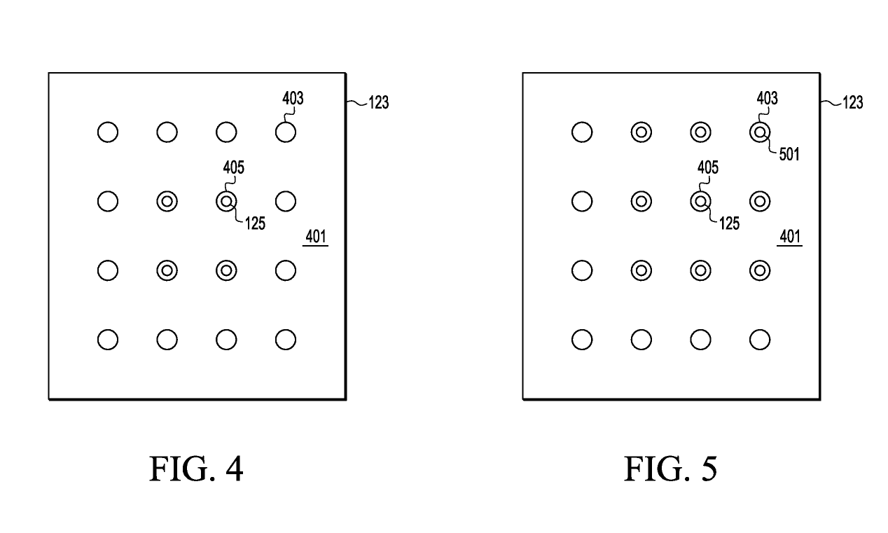

In some embodiments, the probe head 123 is designed such that pins (or other probe contact structures) can be added or removed so that the number of pins of the probe head can be changed when testing different configurations of electronic components. For example, FIG. 4 shows a bottom view of probe head 123. In FIG. 4, bottom side 401 of probe head 123 includes 16 openings (403, 405) where probe pins may be located and extend out from bottom side 401 of each opening to contact the device under test. In the embodiment of FIG. 4, some of the openings (405) include a probe pin (125) located therein. The other openings (403) do not include probe pins. In the embodiment shown, only four of the sixteen openings have probe pins. In this configuration, probe head 123 is configured to test a component that has 4 terminals that need to be accessed during testing.

FIG. 5 is another view of the bottom side 401 of probe head 123. In the view of FIG. 5, a different number of probe pins (501) are located in the holes (403, 405) of probe head 123. In FIG. 9, there are nine probe pins (125) in nine holes of the probe head. In this configuration, probe head 123 is configure to test a component that has 9 terminals that need to be accessed for testing.

In other configurations, all of the openings of a probe block may have a probe pin. Also in other configurations, the openings with probe pins are not necessarily adjacent to each other. With a particular test configuration, whether an opening includes a probe pin depends upon the location and number of external conductive structures (e.g. pads) of the component being tested under the particular configuration.

In one embodiment, the openings have a spacing of 0.4 mm, but may be of other spacings in other embodiments. Also in other embodiments, the probe head may have a greater number of openings. For example, in one embodiment, a probe head may include 284 openings.

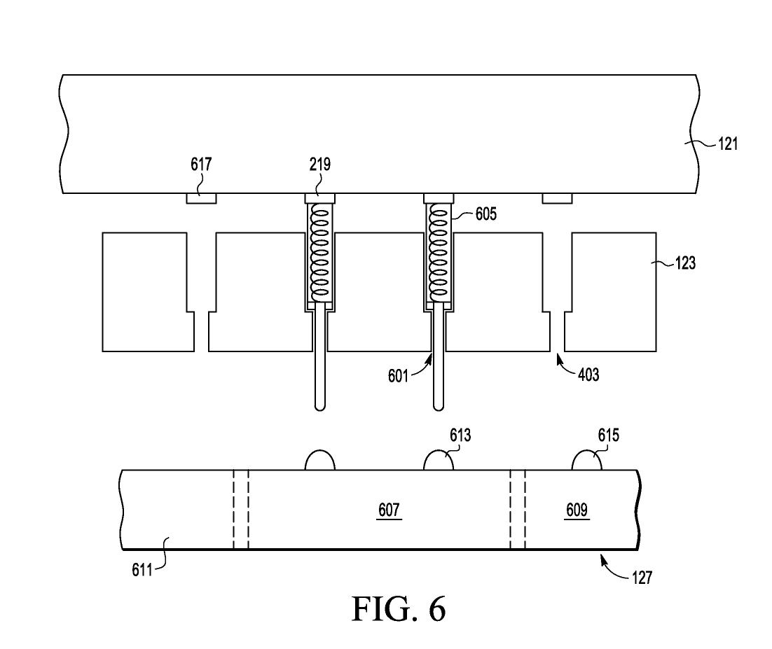

FIG. 6 is side view of probe card 119 located over wafer 127. Shown in FIG. 6 are two pogo probe pins (605) located in the openings (601). The other openings of probe head 123 shown in FIG. 6 (e.g. opening 403) do not include probe pins. The probe pins (605) contact pads (219) of interconnect board 121. The pads (219, 617) are coupled to the probe side terminals (e.g. 211) of interconnect board 121 by conductive traces and vias (not shown) embedded in board 121. In one embodiment, probe head 123 is attached to interconnect board 121 by screws, but may be attached my other attachment devices.

In one embodiment, the pins (605) are selectively and manually placed in probe head 123 prior to its attachment to interconnect board 121. To test a different type of device, the probe head is removed and a different number and/or configuration of probe pins are inserted into probe head 123.

To test a die area of a wafer, the chuck (not shown) moves the wafer 127 so that the die area of wafer 127 to be tested is located under the pins 605. The chuck is then brought up so that the probe pins contact solder bumps (613) or other conductive structures of the die under test. After the die area 607 has been tested, the chuck is lowered and moved to where another die area (609) is under the probe pins to be tested, wherein the chuck is raised back up to the testing position. In some embodiments, the test head is raised and lowered and/or the test head is moved laterally to assume different positions over a wafer for testing.

Providing a probe head with removable probe pins allows for the probe head to be customized as per the configuration of the device under test. Furthermore, removing some of the probe pins that are not used for testing may prevent those pins from causing damage to devices adjacent to the device under test. For example, if a probe pin were in opening 403, then that pin may contact the side of bump 615 during the test of die area 607, causing damage to bump 609. However in some embodiments, unused probe pins would not be removed during testing.

In other embodiments, probe head 123 may include a different type of probe contactors (e.g. pads, bumps, springs, leads) other than pogo pins. Still in other embodiments, the pins are not removable from probe head. In other embodiments, probe head 123 is integral with board 121.

In the embodiment shown, only a portion of a wafer (127) is tested at a time. However in other embodiments, the probe head is designed to hold enough pins to test the entire wafer.

System 101 may be used to test other types of devices. For example, system 101 may be used to test a packaged semiconductor device or portions of multiple packaged semiconductor devices.

One embodiment includes an electronic component testing device capable of testing electronic components in a plurality of test configurations. The device includes a probe head for providing a plurality of probe contact structures to an electronic component to be tested and an interconnect board coupled to the probe head. The interconnect board includes a plurality of conductive terminals, each of a first subset of the plurality of conductive terminals is coupled to one of a group of electrical signal lines for coupling to different types of external signals. The interconnect board includes a plurality of conductive lines. Each conductive line of the plurality is coupled between one of a plurality of conductive terminals in a second subset of the plurality of conductive terminals and a terminal for coupling to one of the plurality of probe contact structures. Each conductive terminal of the second subset is couplable by an interconnector of a plurality of interconnectors to a conductive terminal of multiple conductive terminals of the first subset based on a test configuration of the device.

In another embodiment, an electronic component test device includes an interconnect board couplable between a probe head and a test head. The interconnect board includes a probe head area couplable to the probe head. The probe head area includes a plurality of probe conductive terminals. The interconnect board includes one or more conductive terminal areas. Each conductive terminal area includes a plurality of signal side conductive terminals. Each of the plurality of signal side conductive terminals are couplable to convey a testing signal of a plurality of testing signals of the test head. Each conductive terminal area includes a plurality of probe side conductive terminals, each coupled to a respective probe conductive terminal of the plurality of probe conductive terminals. A plurality of interconnectors is configurable to provide different combinations of connections between signal side conductive terminals of the plurality of signal side conductive terminals of a conductive terminal area and probe side conductive terminals of the plurality of probe side conductive terminals of a conductive terminal area for testing electronic components of different configurations.

In another embodiment, a test device includes an interconnect board including a probe interface area couplable to a probe head. The interconnect board includes a first set of conductive terminals coupled to conductors of the probe interface area and a second set of conductive terminals coupled to test signal external conductors of the interconnect board to convey signals from a test head. The interconnect board includes at least one interconnect configurable to couple one conductive terminal in the first set of conductive terminals to one conductive terminal in the second set of conductive terminals during a first test configuration, couple the one conductive terminal in the first set of conductive terminals to another conductive terminal in the second set of conductive terminals during a second test configuration, and couple another conductive terminal in the first set of conductive terminals to the another conductive terminal in the second set of conductive terminals during a third test configuration.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

What is claimed is:

1. An electronic component testing device capable of testing electronic components in a plurality of test configurations, comprising:
a probe head for providing a plurality of probe contact structures to an electronic component to be tested;
an interconnect board coupled to the probe head, the interconnect board including:
a plurality of conductive terminals, each of a first subset of the plurality of conductive terminals is coupled to one of a group of electrical signal lines for coupling to different types of external signals;
a plurality of conductive lines, each conductive line of the plurality is coupled between one of a plurality of conductive terminals in a second subset of the plurality of conductive terminals and a terminal for coupling to one of the plurality of probe contact structures; and
wherein each conductive terminal of the second subset is couplable by an interconnector of a plurality of interconnectors to a conductive terminal of multiple conductive terminals of the first subset based on a test configuration of the device.

2. The device of claim 1, wherein for at least some test configurations of the device, not all of the second subset of the plurality of conductive terminals are coupled to a conductive terminal of the first subset.

3. The device of claim 1, wherein the different types of external signals include at least one of a group consisting of: an analog ground signal, a digital ground signal, a power signal, an information signal.

4. The device of claim 1, further comprising a plurality of contact pads on the interconnect board coupled to the first subset of the plurality of conductive terminals for conveying the external signals.

5. The device of claim 1, further comprising:
a tester interface; and
a test head coupled to the tester interface, wherein the tester interface conveys the different types of external signals between the test head and the first subset of the plurality of conductive terminals on the interconnect board.

6. The device of claim 1, further comprising the plurality of probe contact structures.

7. The device of claim 6 wherein the plurality of probe contact structures includes a plurality of probe pins that are selectively removable from the probe head depending upon the test configuration of the device.

8. The device of claim 1, wherein the plurality of interconnects include interconnects that are characterized as one type of a group consisting of: jumpers, switches, dip switches, resistors, wires, solid state relays, electromechanical relays, multiplexer, and receptacles.

9. An electronic component test device comprising:
an interconnect board couplable between a probe head and a test head, the interconnect board includes:
a probe head area couplable to the probe head, the probe head area including a plurality of probe conductive terminals;
one or more conductive terminal areas, each conductive terminal area including:
a plurality of signal side conductive terminals, each of the plurality of signal side conductive terminals are couplable to convey a testing signal of a plurality of testing signals of the test head;
a plurality of probe side conductive terminals, each coupled to a respective probe conductive terminal of the plurality of probe conductive terminals;
a plurality interconnectors configurable to provide different combinations of connections between signal side conductive terminals of the plurality of signal side conductive terminals of a conductive terminal area and probe side conductive terminals of the plurality of probe side conductive terminals of the conductive terminal area for testing electronic components of different configurations.

10. The device of claim 9, further comprising the probe head, wherein the probe head comprises a plurality of probe pins couplable to the plurality of probe side conductive terminals.

11. The device of claim 10, wherein at least some of the probe pins of the plurality of probe pins are selectively removable from the probe head to accommodate for different electronic component configurations.

12. The device of claim 10 wherein the probe head and the plurality of probe pins are designed to test die on a semiconductor wafer.

13. The device of claim 10, wherein the plurality of probe pins are spring-loaded.

14. The device of claim 9, wherein the plurality of probe side conductive terminals are couplable to different ones of the plurality of signal side conductive terminals based on a configuration of an electronic component to be tested.

15. The device of claim 9, wherein the plurality of testing signals includes at least one of a group consisting of: an analog ground signal, a digital ground signal, a power signal, and an information signal.

16. The device of claim 9, further comprising a plurality of contact pads on the interconnect board for coupling to connectors that provide the plurality of testing signals of the test head.

17. The device of claim 16, further comprising:
a tester interface; and
a test head coupled to the tester interface, wherein the tester interface conveys the plurality of testing signals between the test head and the contact pads of the interconnect board.

18. The device of claim 9, wherein the plurality of interconnects include interconnects that are characterized as one type of a group consisting of: jumpers, switches, dip switches, resistors, wires, solid state relays, electromechanical relays, multiplexer, and receptacles.

19. A test device comprising:
an interconnect board including:
a probe interface area couplable to a probe head;
a first set of conductive terminals coupled to conductors of the probe interface area;
a second set of conductive terminals coupled to test signal external conductors of the interconnect board to convey signals from a test head;
at least one interconnect configurable to:
couple one conductive terminal in the first set of conductive terminals to one conductive terminal in the second set of conductive terminals during a first test configuration, and
couple the one conductive terminal in the first set of conductive terminals to another conductive terminal in the second set of conductive terminals during a second test configuration, and
couple another conductive terminal in the first set of conductive terminals to the another conductive terminal in the second set of conductive terminals during a third test configuration.

20. The device of claim 19, wherein to accommodate testing different configurations of contacts on different semiconductor wafers, different ones of the second set of conductive terminals are couplable to respective probe pin pads in the probe interface area based on a configuration of contacts of a semiconductor wafer to be tested.
